(19) United States
(12) Patent Application Publication
(10) Pub. No.: US 2012/0052189 A1
(43) Pub. Date: Mar. 1, 2012

(54) VAPOR DEPOSITION SYSTEM

(76) Inventors: Litian Liu, Fremont, CA (US); Erel Milshtein, Cupertino, CA (US); Rick C. Powell, Ann Arbor, MI (US); Michael Rivkin, Los Altos, CA (US)

(21) Appl. No.: 13/221,143

(22) Filed: Aug. 30, 2011

Related U.S. Application Data
(60) Provisional application No. 61/378,215, filed on Aug. 30, 2010.

(51) Int. Cl. C23C 16/52; B05C 11/10

(52) U.S. Cl. 427/8; 118/715; 118/710

(57) ABSTRACT

A vapor deposition process can be used to create layers within a photovoltaic module.

### CLAIM FOR PRIORITY

This application claims priority under 35 U.S.C. §119(e) to Provisional U.S. Patent Application Ser. No. 61/378,215, filed on Aug. 30, 2010, which is hereby incorporated by reference.

### TECHNICAL FIELD

Embodiments of the present invention generally relate to vapor deposition of semiconductor materials onto substrates.

### BACKGROUND

Vapor deposition can be accomplished by vaporizing a material and directing the vaporized material onto a substrate. Upon contacting the substrate, the vaporized material condenses and solidifies to form a film. Deposition rate is affected by many factors, including temperature, pressure, and orifice geometry. Precise control of the deposition rate is required to produce a uniform film thickness, but achieving precise control can be challenging.

### DESCRIPTION OF DRAWINGS

FIG. 1 is a perspective view of a vapor deposition system.

FIG. 2 is a cross-sectional perspective view of the vapor deposition system of FIG. 1

FIG. 3 is a cross-sectional view of a vapor deposition system in a first position.

FIG. 4 is a cross-sectional view of the vapor deposition system of FIG. 3 in a second position.

FIG. 5 is a cross-sectional view of a vapor deposition system.

FIG. 6 is a cross-sectional view of a vapor deposition system.

FIG. 7 is a cross-sectional view of a vapor deposition system.

FIG. 8 is a perspective view of multiple shutters.

FIG. 9 is a perspective view of a shutter having a sculpted edge.

### DETAILED DESCRIPTION

A thin film may be formed on a substrate through a vapor deposition process. During the process, a semiconductor material may be vaporized and deposited onto a target substrate. A vapor deposition system may include a chamber, a vapor source disposed within the chamber, and an adjustable orifice. The vapor source, which can be a crucible or vapor boat, may be configured to hold a material in a solid or liquid form. One or more heaters may transfer heat to the melt material contained in the vapor source causing the material to shift from a solid or liquid phase to a vapor phase. A vacuum may be applied to an inner volume of the chamber thereby causing the vapor to exit the chamber through the orifice and onto the substrate. The vapor may condense upon reaching the substrate thereby forming a thin film of material on the surface of the substrate. The thickness and uniformity of the deposited film can be affected by many factors including temperature, pressure, and orifice geometry. The challenge of controlling film thickness and uniformity can be addressed by including an adjustable orifice as described herein.

Vapor deposition systems for depositing a thin film on a substrate are described, for example, in U.S. application Ser. No. 12/623,367, filed Nov. 20, 2009, U.S. application Ser. No. 11/380,073, filed Apr. 25, 2006, U.S. application Ser. No. 11/380,079, filed Apr. 25, 2006, U.S. application Ser. No. 11/380,088, filed Apr. 25, 2006, and U.S. application Ser. No. 11/380,095, filed Apr. 25, 2006, each of which is incorporated by reference in its entirety.

In one aspect, a vapor deposition apparatus may include a chamber having an adjustable orifice and a vapor source mounted within the chamber. The size of the adjustable orifice may range from 3 mm to 50 mm. Preferably, the size of the adjustable orifice may range from 5 mm to 20 mm. The apparatus may include a feed port configured to provide melt material to the vapor source. The apparatus may include one or more heating elements within a chamber wall. The apparatus may include one or more heating elements within a vapor source wall. The vapor source may include monolithic graphite. The chamber may include monolithic graphite. The apparatus may include a conveyor system mounted proximate to the adjustable orifice. The apparatus may include a layer of high-temperature insulation adjacent to an outer surface of the chamber. The apparatus may include a heat shield adjacent to the high temperature insulation. The vapor source may be mounted on a base. The apparatus may include an actuator configured to move the vapor source relative to the chamber. The size of the adjustable orifice may be controlled by the position of the vapor source relative to the chamber.

In another aspect, a method for manufacturing a film on a substrate may include heating a material in a chamber to produce a vaporized material, determining a deposition rate of the vaporized material exiting an orifice in the chamber, and adjusting the size of the orifice to produce a target deposition rate of the vaporized material. The method may include adjusting a temperature within the chamber to produce a target deposition rate. The method may include adjusting a pressure within the chamber to produce a target deposition rate. The deposition rate may be determined by measuring a thickness of a material deposited on a substrate proximate to the orifice. The orifice size may be adjusted by moving a vapor source relative to the chamber. The size of the orifice may be increased if the deposition rate is less than the target deposition rate. Conversely, the size of the orifice may be decreased if the deposition rate is greater than the target deposition rate. Adjusting the orifice size may include moving one or more shutters relative to the chamber. Adjusting the orifice size may include moving a shutter relative to the chamber, where the shutter has a sculpted edge.

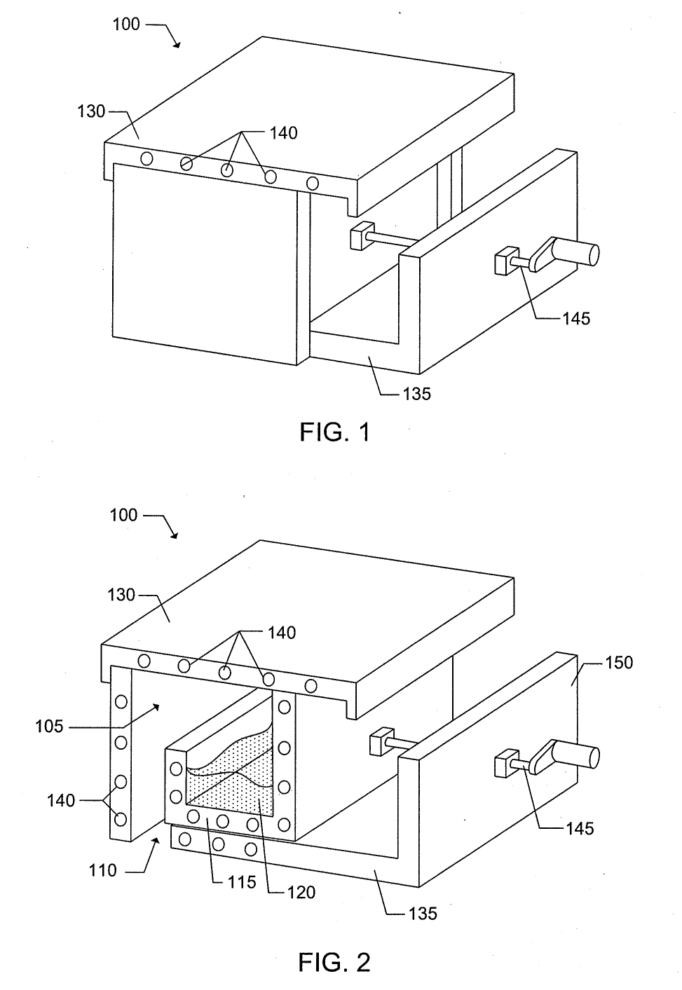

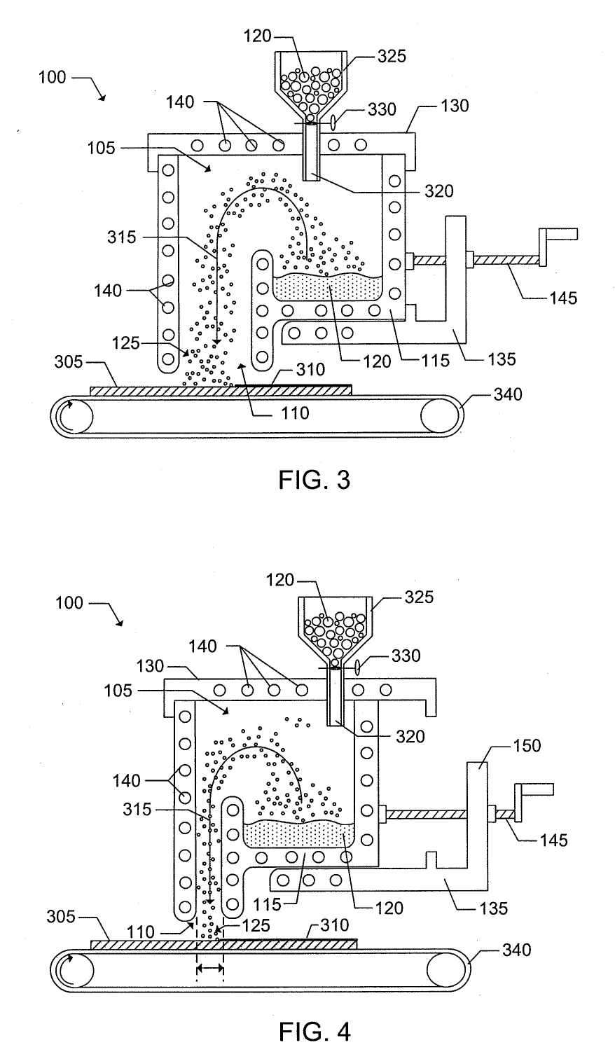

As shown by way of example in FIG. 1, a vapor deposition system 100 may include a chamber 105 having an adjustable orifice 110 and a vapor source 115 disposed within the chamber 105. The vapor source 115 may be mounted within the chamber 105. The vapor source 115 may be a crucible, vapor boat, or any other suitable vessel capable of receiving and holding a melt material 120 at a high temperature. The vapor source 115 may be configured to receive a melt material 120, such as semiconductor material, in any suitable form. For example, pellets, powder, or a continuous wire feed of melt material 120 may be added to the vapor source 115 through a feed port connected to the chamber, as shown in FIGS. 3 and 4. Alternately, the melt material 120 may be preheated and introduced to the vapor source 115 as a liquid. Once the material 120 is within the confines of the vapor source 115, energy may be added to the material to cause evaporation. The vaporized material may form a plume 125 that can be directed through the adjustable orifice 110 and onto a substrate to form a film. Movement of the plume 125 can be controlled by establishing a pressure differential between the vapor source and the adjustable orifice.

The vapor source 115 may accommodate any suitable vaporizable material. The melt material 120 may include any suitable metal such as Al, Cu, In, or Ga. In addition, the melt material 120 may include a semiconductor material such as cadmium telluride or indium sulfide. In one embodiment, the melt material 120 may be deposited on the substrate 305 to form a semiconductor layer for a photovoltaic module.

The chamber 105 may be constructed from any suitable material such as, for example, a high temperature metal alloy, a cermet, or a refractory material. A refractory material is a non-metallic material that remains chemically and physically stable at temperatures above 1,000 degrees Fahrenheit. Common refractory materials include oxides of aluminum, oxides of silicon, oxides of magnesium, and oxides of calcium. Refractory materials also include zirconium dioxide, boron nitride, silicon carbide, carbon, and graphite. Due to its machinability characteristics, monolithic graphite may work well.

A vapor path 315 provides a pathway for vaporized material to travel from the vapor source 115 to the adjustable orifice 110. The vaporized material may be guided along the vapor path 315 by one or more inner surfaces of the chamber 105. Migration of the vapor along the vapor path 315 may be promoted by establishing a pressure differential between the inner volume of the chamber 105 and the ambient environment. By reducing the ambient pressure, vapor forming near the vapor source 115 may seek to exit the chamber 105 via the adjustable orifice 110. Upon exiting the orifice 110, the plume 125 encounters a substrate 305, condenses, and solidifies to form a thin film 310. The substrate 305 may be travel proximate to adjustable orifice on a conveyor system 340. The speed of the conveyor system 340 can be used to control film 310 thickness.

The chamber may include a lid 130. The lid 130 may serve as a cover for the chamber 105 and vapor source 115 and may guide the vapor plume 125 to the orifice 110, thereby serving as a guiding surface of the vapor path 315. The lid 130 may be detachable from the chamber 105. Removal of the lid 130 may provide access to the vapor source 115 and thereby facilitate replenishing of the melt material 120 within the vapor source 115. If the lid 130 is attached to the chamber 105, any suitable form of attachment may be used. For example, the lid 130 may be hingedly attached to the chamber 105. Similar to the chamber 105, the lid 130 may be constructed from any suitable material such as, for example a composite material. The lid 130 may include one or more heaters 140 adjacent to, or disposed within it. As a result, the lid 130 may provide heat to the melt material 120 and help ensure a uniform temperature within the chamber 105 to prevent condensation of vaporized material on the inner surface of the chamber 105 and lid 130.

The vapor deposition system 100 may include a base 135. The base 135 may serve as a platform for the chamber 105. The base 135 may be constructed from any suitable material such as, for example, monolithic graphite. The base 135 may include one or more heaters 140 adjacent to, or disposed within it. Heating the base 135 may prevent the base from acting as heat sink that draws heat from the chamber 105. By heating the base 135, the thermal stability of the vapor deposition system 100 is improved. Thermal stability can be further enhanced by constructing the base 135 from a material having a low thermal conductivity.

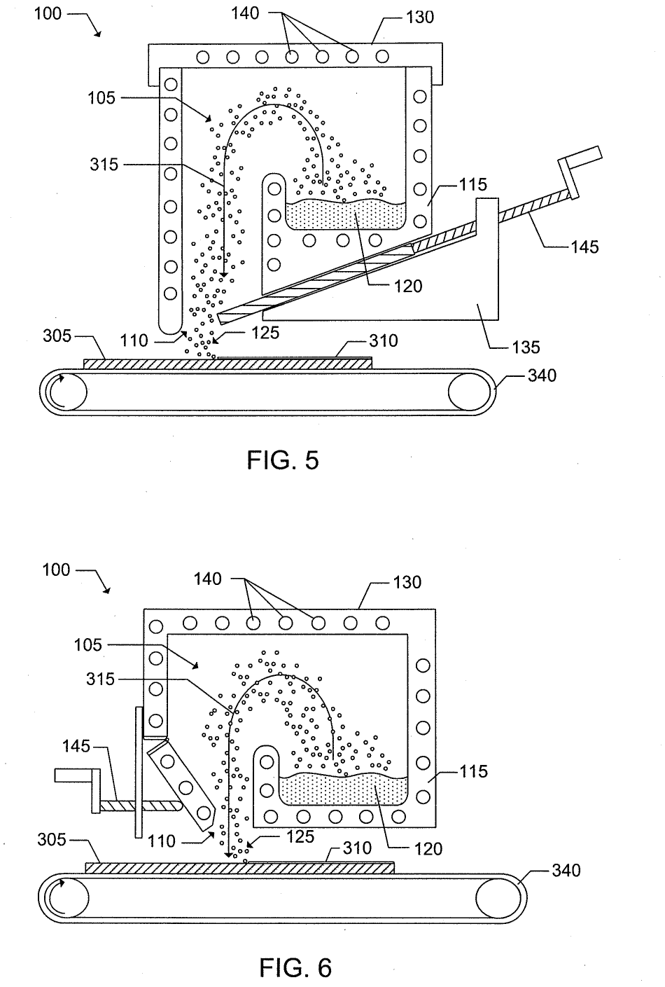

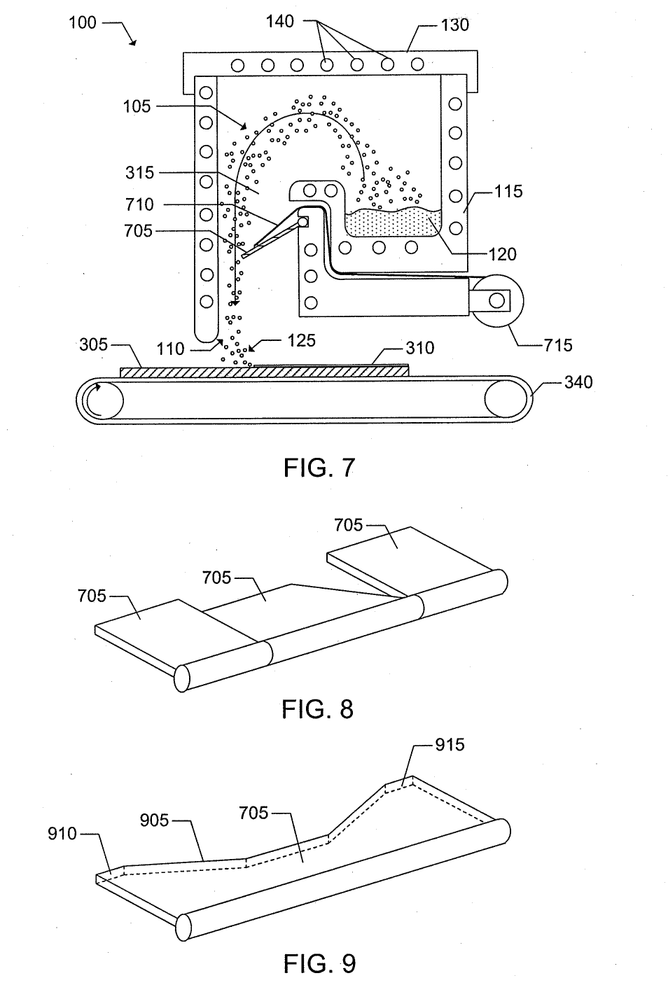

The vapor deposition system 100 may contain at least one adjustable orifice 110. The adjustable orifice 110 may be formed between two parts that move relative to each other. The adjustable orifice is not limited to a single configuration. Accordingly, any suitable configuration may be used to provide an adjustable orifice. Several examples of suitable configurations are shown in FIGS. 2, 4, 5, 6 and 7. In each embodiment, one part moves relative to a second part to alter the geometry of the adjustable orifice 110. For example, in FIG. 7 a shutter 705 may move relative to the vapor source 115 to provide an adjustable orifice 110. The shutter 705 may be actuated by a cable 710 attached to a crank system 715.

The size of the adjustable orifice 110 may be changed to alter the deposition rate of vaporized material onto the substrate 305. The size of the orifice 110 may be adjusted in between manufacturing processes or during a manufacturing process based on in-process feedback. For instance, a metrology system may measure the thickness of the film layer 310 being deposited on the substrate. If the film layer 310 is too thin, the orifice size may be increased to provide a higher deposition rate. Conversely, if the layer 310 is too thick, the orifice size may be decreased to provide a lower deposition rate. The system may adjust the orifice size based on system parameters such as temperature, pressure, and quantity of melt material being introduced to the vapor source 115. The size of the adjustable orifice 110 may be the width of the orifice as shown in FIG. 4. The size of the adjustable orifice 110 may range from 3 mm to 50 mm. Preferably, the size of the orifice 110 may range from 5 mm to 20 mm. Alternately, the size of the adjustable orifice may be the cross-sectional area of the orifice measured along a horizontal plane. The size of the adjustable orifice 110 may range from 0.5 cm² to 800 cm². Preferably, the size of the orifice 110 may range from 1 cm² to 150 cm². The orifice 110 may have any suitable shape such as, for example, square, rectangular, round, oval, or triangular.

An actuator 145 may be configured to adjust the size of the adjustable orifice 110. For example, the vapor source 115 may be seated on the base 135 and may slide relative to the base with assistance from the actuator 145. The actuator 145 may extend between the vapor source 115 and the base 135 and may cause relative motion between the vapor source 115 and the base 135. For example, the actuator 145 may draw the vapor source 115 toward the upright portion 150 of the base 135 thereby enlarging the size of the adjustable orifice 110 as shown in FIG. 3. Alternately, the actuator 145 may push the vapor source 115 away from an upright portion 150 of the base 135 thereby reducing the size of the adjustable orifice 110 as shown in FIG. 4. The actuator 145 may be any suitable linear actuator such as, for example, a servomechanism, a screw, a hydraulic cylinder, or a pneumatic cylinder.

To promote phase transformation of the melt material 120 contained within the vapor source 115, the vapor deposition system 100 may include an energy source proximate to the vapor source 115 and melt material 120. The energy source may include an electron-beam to heat and evaporate the material. Alternately, the energy source may include one or more resistive heaters 140. For example, one or more resistive heaters 140 may be disposed within the walls of the chamber 105, vapor source 115, base 135, and lid 130. The resistive heaters 140 may be any suitable heating elements such as, for example, graphite rod heaters. The resistive heaters 140 may include any suitable metal such as, for example, tungsten, tantalum, or molybdenum.

Holes may be formed in the walls of the chamber 105, vapor source 115, lid 130, and base 135 to accommodate the heaters 140. For example, cylindrical holes may be drilled in the chamber walls to accommodate cylindrical-shaped graphite rod heaters. Alternately, the heaters may be affixed to outer surfaces of the vapor deposition system 100 whereby heat is conducted through the walls to an inner volume of the chamber 105.

The heaters 140 may be connected to a temperature control system. The temperature control system may include one or more temperature measuring devices such as, for example, thermocouples, thermopiles, pyrometers, or temperature dependent resistors (TDR) for measuring the temperature within the apparatus. For example, thermocouples may be embedded within the walls of the chamber 105, vapor source 115, lid 130, and base 140. The thermocouples may provide feedback to the temperature control system. Based on feedback, power distributed to the heaters 140 may be ramped up or ramped down to provide desirable deposition rates. For example, if thermocouple feedback indicates the crucible temperature is below the melting point of the melt material 120, the temperature control system may increase power to the heaters 140. Conversely, if thermocouple feedback indicates the crucible temperature is significantly above the melting point of the melt material 120, the temperature control system may reduce power to the heaters 140.

The evaporation source may include a feed port 320 that serves as a pathway to the vapor source 115 from outside the chamber 105. For example, the feed port 320 may pass through the lid 130 and provide a direct gravity-fed pathway to the vapor source 115 as shown in FIGS. 3 and 4. The feed port 320 allows melt material 120 to be added to the vapor source 115 without having to remove the lid 130. This is desirable, since removing the lid 130 may cause temperature fluctuations and deposition rate instability. The feed port 320 allows melt material 120 to be replenished without significantly disrupting the deposition process.

A hopper 325 may be connected to a top end of the feed port 320 for ease of loading melt material 120. The hopper 325 may contain a valve 330 which allows for accurate metering of melt material 120 through the feed port 320 and into the vapor source 115. The valve 330 may be computer-controlled based on feedback from thermocouples positioned within the system. By monitoring the temperature of the melt material 120 within the vapor source 115, the system can avoid adding too much melt material 120 to the vapor source 115. Adding too much melt material 120 to the crucible is undesirable, since it can reduce the temperature of the melt pool, thereby negatively impacting the evaporation process and causing the deposition rate to fluctuate. If the deposition rate is permitted to fluctuate, the film thickness 310 on the target substrate 305 will also fluctuate. Since film thickness affects solar module performance, permitting fluctuations in film thickness 310 is undesirable.

To better control deposition rates in a direction transverse to the direction of motion, one or more shutters 705 may be included. For instance, the chamber 105 may contain three shutters 705 as shown in FIG. 8, where the shutters can be actuated independent of each other. The number of shutters may range from 1 to 30. Preferably, the number of shutters may range from 1 to 5. By including multiple shutters, deposition rates near the edge of a module may be carefully controlled. For example, the metrology system described above may provide feedback that allows the multiple shutters to be adjusted to control transverse uniformity and overall mass flux, where mass flux is controlled by conveyor speed and deposition rate.

A shutter having a sculpted edge 905 may be used as shown in FIG. 9. The shape of the sculpted edge 905 may be modified to achieve desired deposition rates. For instance, if the deposition rate is too high near the edges of the substrate 305, but is adequate near the middle of the substrate 305, the rate near the edges of the substrate 305 may be reduced by increasing the size of the shutter 705 near a first side 910 and a second side 915. The sculpted edge 905 of the shutter 705 may include a contoured edge, a straight edge, or a combination thereof.

To improve thermal efficiency of the vapor deposition system 100, thermal barriers may be included proximate to the outer surfaces of the system 100. Thermal barriers may include a heat shield and high temperature insulation. The heat shield may be placed around the vapor deposition system 100 to reduce radiation losses to the ambient environment. The heat shield may be constructed from a material having low emissivity, low absorption, and high melting point such as molybdenum or tantalum, which permit reflection of electromagnetic rays. High temperature insulation may be inserted between the outer surfaces of the system 100 and the heat shield. The high temperature insulation can reduce convection and conduction losses to the ambient environment. The insulation may be constructed of any suitable high-temperature material such as, for example, vitreous reticulated carbon, graphite felt, or porous ceramic.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. Also, it should also be understood that the appended drawings are not necessarily to scale, presenting a somewhat simplified representation of various features and basic principles of the invention.

What is claimed is:

1. A vapor deposition apparatus comprising:
a chamber comprising an adjustable orifice; and
a vapor source mounted within the chamber.

2. The apparatus of claim 1, wherein the size of the adjustable orifice ranges from 3 mm to 50 mm.

3. The apparatus of claim 1, wherein the size of the adjustable orifice ranges from 5 mm to 20 mm.

4. The apparatus of claim 1, further comprising a feed port configured to provide melt material to the vapor source.

5. The apparatus of claim 1, further comprising one or more heating elements within a chamber wall.

6. The apparatus of claim 1, further comprising one or more heating elements within a vapor source wall.

7. The apparatus of claim 1, wherein the vapor source includes monolithic graphite.

8. The apparatus of claim 1, wherein the chamber includes monolithic graphite.

9. The apparatus of claim 1, wherein a conveyor system is mounted proximate to the adjustable orifice.

10. The apparatus of claim 1, further comprising a layer of high-temperature insulation adjacent to an outer surface of the chamber.

11. The apparatus of claim 10, further comprising a heat shield adjacent to the high temperature insulation.

12. The apparatus of claim 10, wherein the vapor source is mounted on a base.

13. The apparatus of claim 12, further comprising an actuator configured to move the vapor source relative to the chamber.

14. The apparatus of claim 13, wherein the size of the adjustable orifice is controlled by the position of the vapor source relative to the chamber.

15. A method for manufacturing a film on a substrate, the method comprising:
heating a material in a chamber to produce a vaporized material;
determining the deposition rate of the vaporized material exiting an orifice in the chamber; and
adjusting the size of the orifice to produce a target deposition rate of the vaporized material.

16. The method claim 15, further comprising adjusting a temperature within the chamber to produce a target deposition rate.

17. The method claim 15, further comprising adjusting a pressure within the chamber to produce a target deposition rate.

18. The method claim 15, wherein determining the deposition rate comprises measuring a thickness of a material deposited on a substrate proximate to the orifice.

19. The method of claim 15, wherein adjusting the orifice size comprises moving a vapor source relative to the chamber.

20. The method of claim 15, wherein the size of the orifice is increased if the deposition rate is less than the target deposition rate.

21. The method of claim 15, wherein the size of the orifice is decreased if the deposition rate is greater than the target deposition rate.

22. The method of claim 15, wherein adjusting the orifice size comprises moving one or more shutters relative to the chamber.

23. The method of claim 15, wherein adjusting the orifice size comprises moving a shutter relative to the chamber, wherein the shutter has a sculpted edge.
